(19) United States
(12) Patent Application Publication
(10) Pub. No.: US 2004/0023491 A1
(43) Pub. Date: Feb. 5, 2004

(54) Preparation and use of an abrasive slurry composition

(76) Inventors: Young-Sam Lim, Seoul (KR); Gi-Hag Lee, Seoul (KR); Dong-Jun Lee, Seoul (KR); Kyoung-Moon Kang, Yongin-si (KR); Jae-Hyun So, Seoul (KR); Nam-Soo Kim, Suwon-si (KR)

Correspondence Address: HARNESS, DICKEY & PIERCE, P.L.C., P.O. BOX 8910, RESTON, VA, 20195, US

(21) Appl. No.: 10/384,558

(22) Filed: Mar. 11, 2003

(30) Foreign Application Priority Data
Aug. 5, 2002 (KR) 2002-46158

(51) Int. Cl. H01L 21/302; H01L 21/461

(52) U.S. Cl. 438/689

(57) ABSTRACT

Particular aqueous slurry compositions including fine abrasive particles and polishing methods for polishing insulating films such as silicon dioxide and silicon nitride using such slurry compositions are provided in which the abrasive particles have a mean particle surface area of at least about 100 m²/g and the slurry compositions include the abrasive particles and at least one additive selected from potassium hydroxide, sodium hydroxide, ammonium hydroxide and amine compounds.

### BACKGROUND OF THE INVENTION

1. Field of the Invention

The present invention relates to abrasive particles, a slurry composition including the abrasive particles, a method for preparing the slurry composition, and a polishing method using the slurry composition and, more particularly, to abrasive particles utilized for polishing an insulation film including oxide, a slurry composition including the abrasive particles, a method for preparing the slurry composition and a method for polishing the insulation film with the slurry composition.

2. Description of the Related Art

Efforts continue to improve the performance of semiconductor devices to meet the increasing demands of information processing devices such as computers, signal processing devices and other electronics. Semiconductor devices having both high performance speed, reliability and/or large storage capacity are required to meet such demands, so efforts continue to improve semiconductor manufacturing processes to increase the integration density, reliability and performance of the resulting semiconductor devices.

Chemical-mechanical polishing (CMP) processes are well known as processes useful in increasing the integration density of semiconductor devices. By employing a CMP process, the non-uniform topography formed on a wafer surface during the manufacture of semiconductor devices can be polished to provide a flat or planarized surface. This polishing may complete the formation of certain structures in addition to providing a smooth surface to simplify or improve subsequent processing steps. CMP processes, for example, may be used in forming shallow trench isolation structures or planarizing an interlayer dielectric film between conductive patterns.

A method for planarizing an interlayer dielectric film is disclosed in U.S. Pat. No. 6,162,368 (issued to Li et al.) and slurries that may be used for polishing oxide films are disclosed in U.S. Pat. No. 6,280,652 (issued to Inoue et al.) and Japanese Laid Open Patent Publication No. 10-172934. Issues relating to the method and equipment used to disperse particles in a liquid to form a slurry are discussed in U.S. Pat. No. 5,904,159 (issued to Kato et al.). As disclosed by Li, an oxide film is polished with a conventional slurry comprising water, silicon oxide abrasive particles and an additive such as potassium hydroxide or an amine-based agent. The silicon oxide abrasive particles are characterized by a mean particle surface area of between approximately 50 and 90 m²/g. As used herein, the mean particle surface area is defined as the area of the primary particles, i.e., the abrasive particles. Hence, when the diameters of the primary particles increase, the mean particle surface area is reduced. On the other hand, the mean particle surface area increases as the diameters of the primary particles decreases. That is, the gap size between the abrasive particles decreases when the diameters of the primary particles become small, while the gap size of the abrasive particles increases according as the diameters of the primary particles become large. The abrasive particles are getting agglomerated as much as the gap size decreases so that the stability of the dispersion of the slurry particles decreases. The mean particle surface area can be measured through the Brunauer Emmett Teller (BET) method.

FIG. 1 is a graph showing the measurement of the thickness of an oxide film across the face of a wafer after polishing with a slurry including silicon oxide abrasive particles having a mean particle surface area of approximately 50 m²/g according to the conventional polishing process. As reflected in FIG. 1, the oxide film on the peripheral portion of the wafer oxide film on the substrate has the thickness of approximately 8,000 Å while the central portion of the oxide film has the thickness of approximately 9,000 Å. Thus, the peripheral portion of the oxide film is polished more than the central portion of the oxide film. This inability of the conventional slurry and CMP process to achieve a uniform layer thickness during the polishing of the oxide film will tend to degrade the uniformity and reliability of the resulting semiconductor devices.

### SUMMARY OF THE INVENTION

In order to improve the uniformity of the polished surface, an exemplary embodiment of the present invention provides an abrasive slurry including abrasive particles for uniformly polishing an entire surface of a thin film and reducing defects in the polished layers remaining on the polished object.

In another exemplary embodiment, the present invention provides a method for preparing a slurry composition for uniformly polishing an object and for reducing defects in the polished object.

In another exemplary embodiment, the present invention provides a polishing method for uniformly polishing an object and for reducing defects in the polished object.

In another exemplary embodiment, present invention provides abrasive particles suitable for use in a slurry composition with the primary abrasive particles having a mean particle surface area of no less than approximately 100 m²/g,

In another exemplary embodiment, the present invention also provides a slurry composition for manufacturing a semiconductor device comprising primary abrasive particles having a mean particle surface area of no less than approximately 100 m²/g, an additive and water.

In another exemplary embodiment, the present invention also provides a method for preparing a slurry for manufacturing a semiconductor device comprising preparing primary abrasive particles having a mean particle surface area of no less than approximately 100 m²/g, mixing the abrasive particles with a water, pressing the mixture and dispersing the abrasive particles by agitating the mixture in a disperser.

Furthermore, in another exemplary embodiment, the present invention provides a method for polishing an object in a semiconductor processing comprising preparing a slurry including primary abrasive particles having a mean particle surface area of at least approximately 100 m²/g, water, and one or more additives including potassium hydroxide, sodium hydroxide, ammonium hydroxide and amine compounds, providing the slurry on a polishing pad, and polishing a surface of the object by contacting the polishing pad with the object while maintaining relative movement between the pad and the object.

According to another exemplary embodiment, the present invention, an object may be polished using the slurry including abrasive particles having a mean particle surface area of at least approximately 100 m²/g to produce a polished surface on the object.

### BRIEF DESCRIPTION OF THE DRAWINGS

The advantages and operation of the exemplary embodiments of the present invention will become readily apparent by reference to the following detailed description when considered in conjunction with the accompanying drawings wherein:

FIG. 1 is a graph showing a polished thickness of an oxide film using a conventional slurry and a conventional polishing process for polishing the oxide film;

FIG. 2 is a graph showing a polished thickness of an oxide film relative to a mean particle surface area of abrasive particles in various slurry compositions;

FIG. 3 is a graph illustrating a polishing uniformity of an oxide film relative to a mean particle surface area of abrasive particles in various slurry compositions;

FIG. 4 is a graph showing a polishing rate of an oxide film relative to a mean particle surface area of abrasive particles in various slurry compositions;

FIG. 5 is a graph showing a polishing rate and a polishing selectivity of an oxide film relative to an amount of an additive in various slurry compositions;

FIG. 6 is a graph illustrating a polishing rate and a polishing selectivity of an oxide film relative to an amount of an additive in various slurry compositions;

FIG. 7 is a graph showing a range of a polishing uniformity of an oxide film relative to a mean particle surface area of abrasive particles in various slurry compositions;

FIG. 8 is a graph illustrating the number of defect points of an oxide film relative to an amount of an additive in various slurry compositions; and

FIG. 9 is a graph reflecting agglomeration in slurry compositions relative to an amount of an additive.

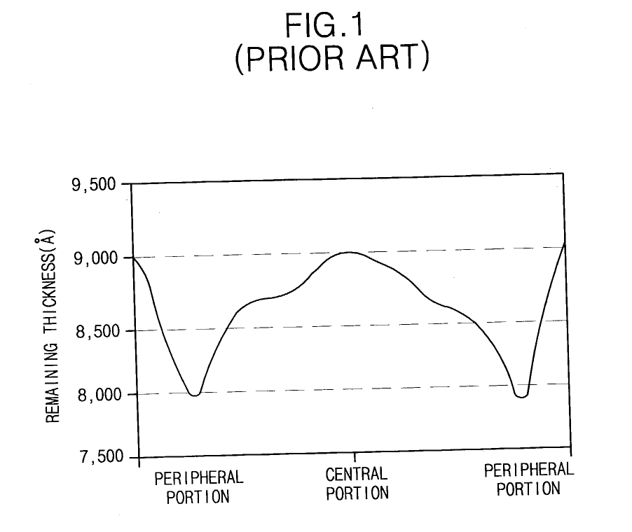

### DESCRIPTION OF THE EXEMPLARY EMBODIMENTS

Hereinafter, the exemplary embodiments of the present invention will be described in detail with reference to the accompanying drawings. In the following drawings, like reference numerals identify similar or identical elements.

Abrasive Particles

Thin films polished using conventional primary abrasive particles having a mean particle surface area of less than approximately 100 m²/g generally exhibit a layer uniformity no better than about 3.0%. The inventors have unexpectedly found that layer uniformity can be improved by using primary abrasive particles having a mean particle surface area of at least approximately 100 m²/g, and possibly a mean particle surface area of at least approximately 140 m²/g. In order to achieve these levels of mean particle surface area, the primary abrasive particles will typically have a mean diameter of no more than about 35 nm.

The abrasive particles may include silica (silicon oxide (SiO₂) powder), ceria (cerium oxide (CeO₂) powder), zirconia (zirconium oxide (ZrO₂) powder), titania (titanium oxide (TiO₂) powder) or alumina (aluminum oxide (Al₂O₃) powder). These compounds maybe used alone or in combination in the formation of abrasive particles or compositions tailored for removing different types of materials. For example, silicon oxide (silica) abrasive particles are typically included in abrasive compositions intended for use in polishing oxide films.

Slurry Composition

The slurry composition of the present invention includes water, an additive and primary abrasive particles having a mean particle surface area of no less than approximately 100 m²/g with the abrasive particles generally comprising between about 0.5 wt % and about 40 wt % of the slurry composition. When the amount of the abrasive particles in the slurry composition falls below approximately 0.5 wt %, the polishing rate (or material removal rate) of the film being polished tends to be unacceptably low. On the other hand, when the amount of the abrasive particles in the slurry composition increases to above about 40 wt %, there is an increased likelihood of scratches being formed in the film being polished. Therefore, abrasive particles according to exemplary embodiments of the present invention are generally included in the slurry composition in a quantity between approximately 0.5 and 40 wt %.

Similarly, when the amount of the additive included in the slurry composition falls below approximately 0.01 wt %, the polishing rate and the polishing uniformity of the film be polished tends to be reduced as the stability of the dispersion of the abrasive particles in the slurry is reduced. Otherwise, the dispersion stability of the abrasive particles may deteriorate and increase the likelihood of scratching the film being polished if the amount of the additive included in the slurry composition exceeds approximately 2.0 wt %. Therefore, the amount of the additive included in the slurry composition is between approximately 0.01 and 2.0 wt %.

Furthermore, the slurry composition may become unacceptably viscous if the quantity of water included in the slurry composition is less than approximately 55 wt %. However, when the amount of the water included in the slurry composition is more than approximately 99.5 wt %, the polishing efficiency of the film to be polished like the polishing rate may be reduced by the lack of abrasive particles and additive. Hence, the amount of the water included in exemplary slurry compositions is between approximately 55 and 99.5 wt %.

As it is described above, the abrasive particles include the primary particles having the diameters of no more than approximately 35 nm. These abrasive particles may include one or more types of particles selected from silica (silicon oxide (SiO₂) powder), ceria (cerium oxide (CeO₂) powder), zirconia (zirconium oxide (ZrO₂) powder), titania (titanium oxide (TiO₂) powder) or alumina (aluminum oxide (Al₂O₃) powder) particles. Though such particles can used alone in the slurry composition, an abrasive mixture containing at least two different types of particles may be included in the slurry composition. The selection of the particular abrasive or abrasives included in a particular slurry may reflect the type of material to be polished using the slurry. For example, silicon oxide (silica) abrasive particles will typically be included in abrasive compositions intended for use in polishing oxide films.

Examples of additives useful in exemplary slurry compositions according to the present invention include potassium hydroxide, sodium hydroxide, ammonium hydroxide and amine compounds. These additives may be used alone or in combination in the slurry composition. For example, when a combination of potassium hydroxide and an amine compound are included in a slurry composition, the polishing rate may be higher than the polishing rate achieved with either additive singly. Examples of amine compounds include quadrivalent ammonium bases or the salts thereof and may be used alone or in combination in the slurry composition. Examples of the quadrivalent ammonium bases include tetramethylammonium hydroxide (TMAH), tetraethylammonium hydroxide (TEAH), tetramethylammonium chloride (TMACI), tetraethylammonium chloride (TEACI), tetramethylammonium fluoride (TMAF), and/or tetraethylammonium fluoride (TEAF). These ammonium bases may be used alone or in combination in the slurry compositions and may serve as a dispersion stabilizer and/or a surfactant in the slurry composition. Although each of the additives may be used singly, the use of at least two additive compounds are may provide improved performance. In particular, when one or more amine compounds are included as an additive, the amount of the amine compound(s) added to the slurry composition is generally between approximately 0.2 and 0.4 wt %. The additive may also include one or more cationic species.

Other additives that may be used include ethanol amine, dimethanol amine, trimethanol amine, ethylene diamine, cetyltrimethylammonium bromide (CTAB), and cetylpyridinium chloride (CPC). Those compounds may be used alone or in combination in the slurry compositions and may improve the polishing selectivity of the film to be polished relative to a nitride film during a polishing process. In order to increase the polishing selectivity of the film to be polished relative to a nitride film, these additives should typically comprise approximately 0.1 wt % of the slurry composition.

Method for Preparing the Slurry Composition

Abrasive particles comprising one or more of silica, ceria, zirconia, titania or alumina are prepared so that the primary abrasive particles typically have diameters of no more than approximately 35 nm. These primary abrasive particles have a mean particle surface area of no less than approximately 100 m²/g.

Water is added to the abrasive particles to form a mixture, the mixture is pressed to be inserted into a disperser. When a homogenizer(manufactured by IKA, Germany) or an ultrasonic dispenser(manufactured by SONIC AND MATERIALS, USA) is employed as the disperser, the dispersion degree of the resulting slurry may be degraded because the primary particles of the abrasive have diameters of no more than approximately 35 nm. Dispersers that

act by colliding the particles within the mixture tend to distribute the abrasive particles more uniformly throughout the mixture. One or more additives that may serve as a dispersion stabilizer and/or surfactant may be added to the mixture in the disperser. The additive may also include one or more compounds selected from potassium hydroxide, sodium hydroxide, ammonium hydroxide and amine compounds.

In the slurry prepared according to an exemplary embodiment of the present invention, the amount of the abrasive particles included in the slurry is typically adjusted to between approximately 0.5 and 40 wt %, the amount of the additive(s) included in the slurry is typically adjusted to between approximately 0.01 and 2.0 wt %, and the amount of the water included in the slurry is adjusted to between approximately 55 and 99.5 wt %.

Polishing Process

A slurry is prepared in accordance with the above-described procedure to provide abrasive particles having a mean surface area of at least approximately 100 m²/g, an additive including potassium hydroxide, sodium hydroxide, ammonium hydroxide or one or more amine compounds or a mixture of these hydroxides and/or amine compounds, and water.

The slurry is dispensed or otherwise provided onto a polishing pad, the polishing pad makes contact with a surface of an object to be polished with relative movement being initiated between the polishing pad and the object to be polished. The relative motion may result from rotation of the polishing pad and the object to be polished in the same direction. Similarly, the relative motion may result from rotation of the polishing pad and the object to be polished in opposite directions. The relative motion may be more complex, incorporating a combination of linear, rotational, revolving, or orbital motions between the polishing pad and the object to be polished. During the polishing, a surface of the object being polished is typically pressed against and makes contact with the polishing pad, the contact being maintained by a force or pressure. Using this configuration, the object may be chemically polished through the action of the slurry with the materials on the surface of the object being polished and/or may be mechanically polished by the relative motion of the object and the polishing pad and by the pressure and contact between the object and the polishing pad.

The abrasive particles in the slurry for the polishing process may include one or more of silica, ceria, zirconia, titania, or alumina particles and may be used for polishing oxide, nitride or metal films. The slurry may also include an additive such as ethanol amine, dimethanol amine, trimethanol amine, ethylene diamine, CTAB or CPC, intended to increase the oxide/nitride selectivity, particularly for polishing an object that includes a first insulation film of nitride and a second insulation film of oxide formed on the first insulation film.

The characteristics of abrasive particles and the slurry will be further described below with respect to experiments conducted with exemplary abrasive particles and slurry compositions and comparative experiments conducted with conventional abrasive particles and slurry compositions.

Experiment 1

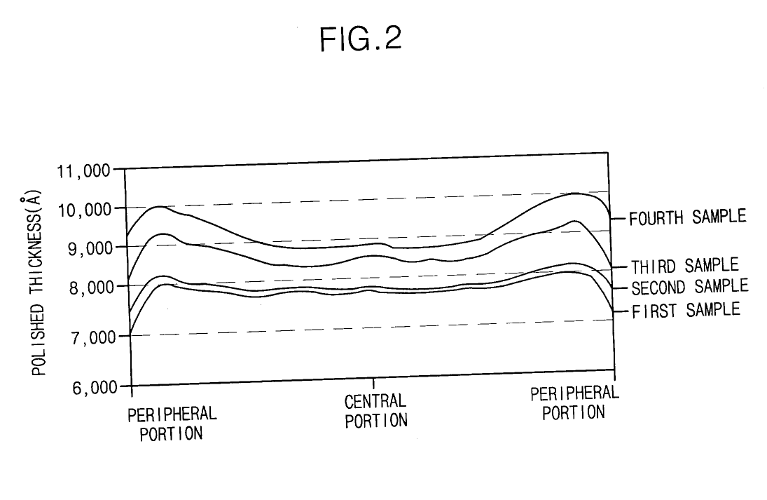

FIG. 2 is a graph showing the polished thickness of the oxide film to be polished relative to the mean particle surface area of the abrasive particles in a series of four slurry compositions.

Referring to FIG. 2, a first sample shows the polishing results achieved on an oxide film using a slurry with silicon oxide abrasive particles having the mean particle surface area of approximately 160 m²/g (the primary particles of the abrasive particles having the diameters of between approximately 5 and 15 nm). Also, the second sample shows the polishing results achieved on an oxide film using a slurry substantially identical to the first slurry but using silicon oxide abrasive particles having the mean particle surface area of approximately 140 m²/g and diameters of approximately 5 and 15 nm.

As also shown in FIG. 2, the third and fourth samples show the polishing results achieved on an oxide film using slurries having a liquid component substantially identical to the first and second samples but using silicon oxide abrasive particles having the mean particle surface area of approximately 90 m²/g (third sample) and approximately 50 m²/g (fourth sample) in which diameters of the primary particles of the third sample were identical to those of the first sample while diameters of the primary particles of the fourth sample were approximately 50 nm.

As reflected in FIG. 2, in the first and the second samples the thickness of the central portion of the oxide film was approximately identical to that of the peripheral portion of the oxide film after polishing. On the other hand, in the third and the fourth samples, the peripheral portion of the oxide film was thicker than the central portion of the oxide film after polishing. As reflected in FIG. 2, therefore, the uniformity of a polished oxide film may be improved by increasing the mean particle surface area of the abrasive particles used in the slurry (that is, reducing the diameters of primary particles in the abrasive particles).

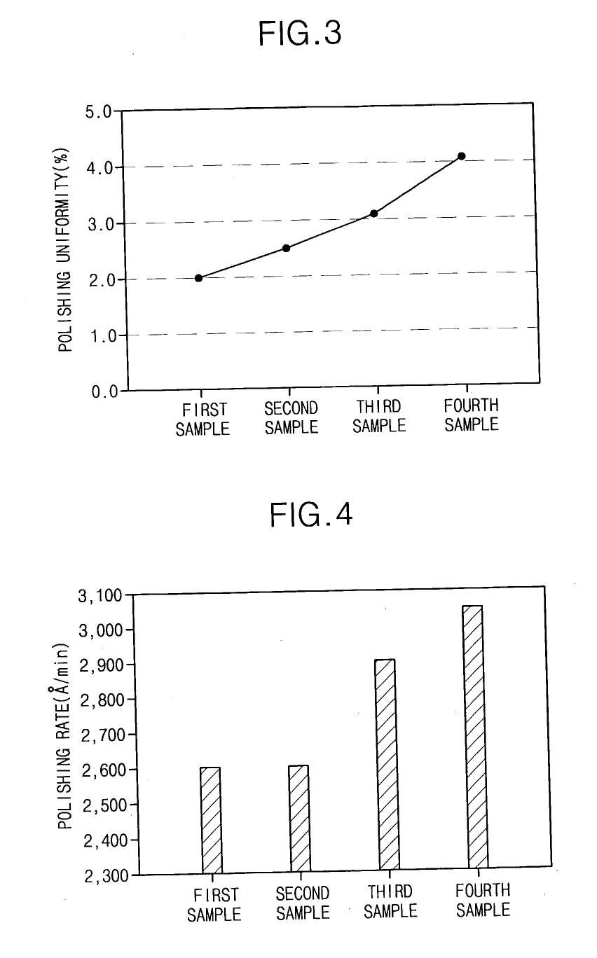

FIG. 3 is a graph illustrating the polishing uniformity of the oxide film relative to the mean particle surface area of the abrasive particles for the slurry compositions described above for samples one through four. As reflected in FIG. 3, the first sample was able to achieve a degree of polishing uniformity more than twice as good as the polishing uniformity obtained using the fourth sample.

FIG. 4 is a graph showing the polishing rate of the oxide film relative to the mean particle surface area of the abrasive particles for the slurry compositions described above for samples one to four. As reflected in FIG. 4, the polishing rates achieved with the first and the second samples were somewhat lower than those achieved with the third and the fourth samples. Specifically, the polishing rate achieved with the first sample was approximately 2,600 Å/min while the polishing rate of the fourth sample was approximately 3,050 Å/min. In general, the polishing rates achieved using slurry compositions with the smaller abrasive particles were lower than those achieved using slurry compositions having larger abrasive particles. Therefore, to improve the polishing rate of the oxide film, an additive comprising potassium hydroxide, sodium hydroxide, ammonium hydroxide, an amine compound or a mixture of these hydroxides or compounds, may be added to slurry compositions having smaller abrasive particles.

Experiment 2

FIG. 5 is a graph showing the polishing rate and the polishing selectivity of the oxide film relative to the amount of the additive in slurry compositions of five samples respectively. As reflected in FIG. 5, the seventh sample shows the polishing results achieved on an oxide film polished using a slurry composition including potassium hydroxide at approximately 0.37 wt % and silicon oxide abrasive particles having a mean particle surface area of approximately 130 m²/g. Similarly, the eighth and ninth samples represent the polishing results achieved on an oxide film using a substantially identical slurry composition in which the potassium hydroxide content was increased to approximately 0.5 wt % and 0.66 wt % respectively.

Also reflected in FIG. 5 are fifth and sixth samples reflecting the polishing results achieved on an oxide film using slurry compositions including an additive of approximately 0.4 wt % potassium hydroxide and silicon oxide abrasive particles having the mean particle surface area of approximately 50 m²/g and approximately 90 m²/g respectively.

As shown in FIG. 5, the polishing rates of the eighth and the ninth samples were approximately identical to those of the sixth sample. Therefore, when a sufficient quantity of an additive including potassium hydroxide is incorporated into a slurry composition including abrasive particles having a mean particle surface area of at least approximately 100 m²/g, it is possible to maintain polishing rates substantially equivalent to those of the conventional slurry compositions for an oxide film.

Further, as also reflected in FIG. 5, the polishing uniformities of the seventh, the eighth and the ninth samples were each improved relative to the uniformity achieved with the conventional slurry compositions of the fifth and the sixth samples. It may be concluded, therefore, that the noted improvement in the uniformity of the polished oxide film was not degraded by including an elevated amount of an additive including potassium hydroxide in a slurry including abrasive particles having a mean particle surface area of more than approximately 100 m²/g and thereby obtain improved oxide polishing rates.

Accordingly, because the polishing rate of the oxide film may tend to be reduced for smaller abrasive particles, an additive, or an increased quantity of an additive, may be added to slurry compositions having abrasive particles with a mean particle surface area of more than 100 m²/g to increase the polishing rate while maintaining the improved polishing uniformity of the oxide film that may be achieved with such slurry compositions.

Experiment 3

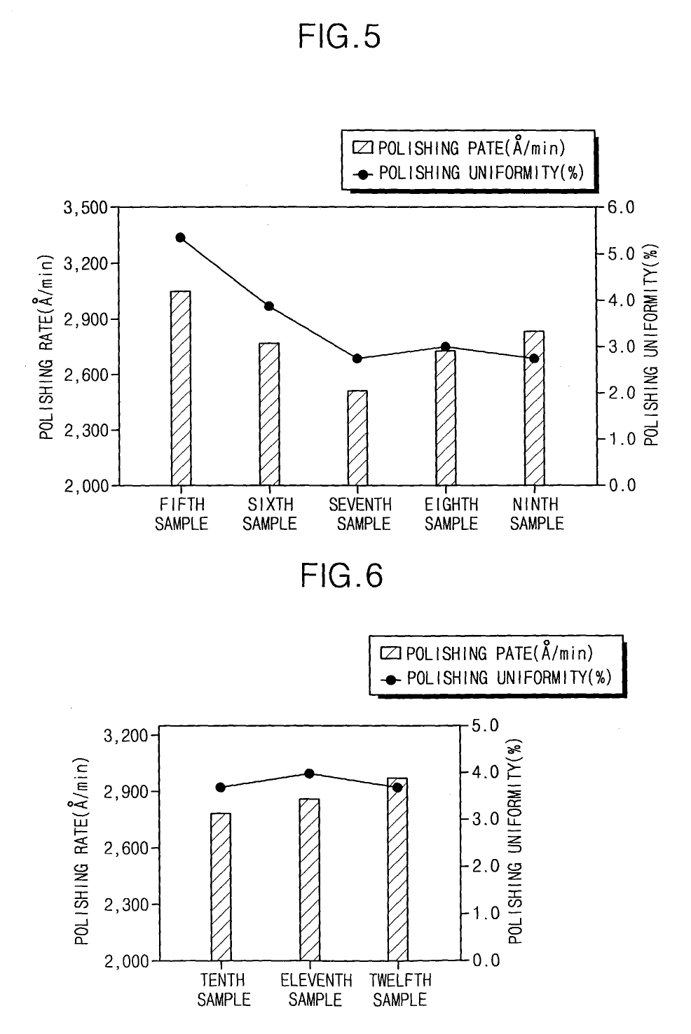

FIG. 6 is a graph illustrating the polishing rate and the polishing selectivity of the oxide film relative to the amount and components in the additive in the slurry composition.

Referring to FIG. 6, an eleventh sample reflects the polishing results achieved on an oxide film using a slurry composition including tetramethylammonium hydroxide at approximately 0.2 wt %, potassium hydroxide at approximately 0.468 wt % and silicon oxide abrasive particles having a mean particle surface area of approximately 100 m²/g. In addition, a twelfth sample represents the polishing results achieved on an oxide film using a slurry composition including tetramethylammonium hydroxide at approximately 0.4 wt %, potassium hydroxide at approximately 0.468 wt % and silicon oxide abrasive particles having a mean particle surface area of approximately 100 m²/g.

Also in FIG. 6, a tenth sample shows the polishing result achieved on an oxide film using a slurry composition including potassium hydroxide at approximately 0.468 wt % and silicon oxide abrasive particles having the mean particle surface area of approximately 100 m²/g. In the tenth sample, however, the slurry additive did not include any tetramethylammonium hydroxide.

As shown in FIG. 6, the polishing rates of the eleventh and the twelfth samples were higher than that of the tenth sample while the polishing uniformities of the eleventh and the twelfth samples remained similar to that of the tenth sample. Thus, it can be noted that the polishing rate of the oxide film increased with additives having increasing levels of tetramethylammonium hydroxide in combination with potassium hydroxide. Further, although the polishing rate of the oxide film improved with increasing amounts of tetramethylammonium hydroxide, the polishing uniformity of the oxide film achieved with the various slurry compositions remained relatively unaffected.

Experiment 4

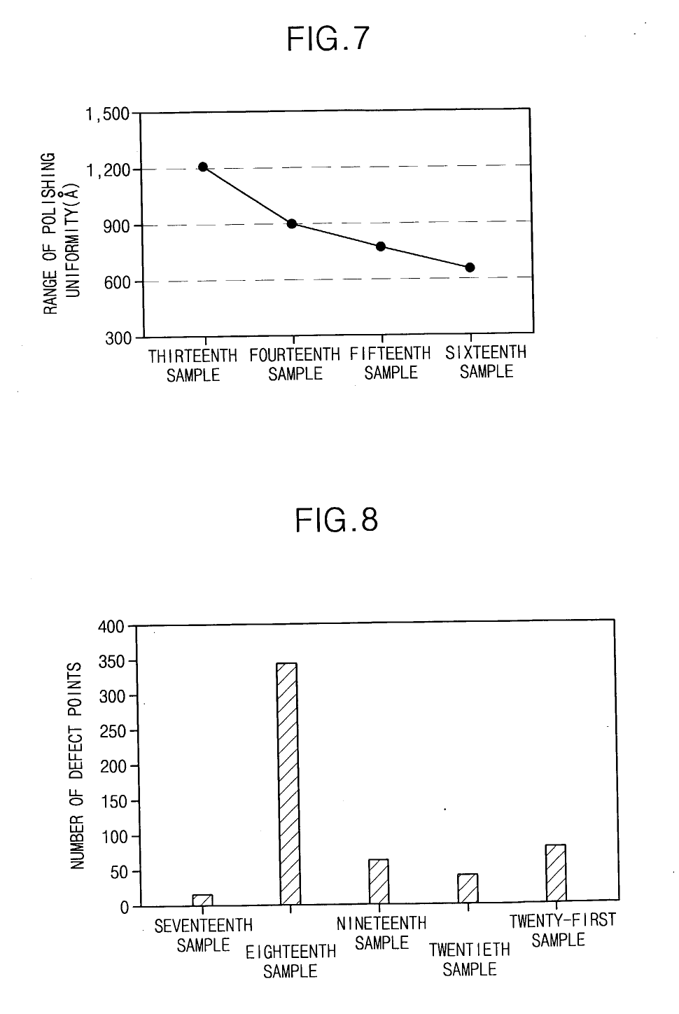

FIG. 7 is a graph showing the range of the polishing uniformity of an oxide film relative to the mean particle surface area of the abrasive particles in certain exemplary and conventional slurry compositions. As reflected in FIG. 7, a sixteenth sample represents the polishing result achieved on an oxide film using a slurry composition identical to that of the first sample, and a fifteenth sample shows the polishing result achieved on an oxide film using a slurry composition identical to that of the second sample.

As also reflected in FIG. 7, a thirteenth sample indicates the polishing result achieved on an oxide film using a slurry composition identical to that of the third sample, and a fourteenth sample shows the polishing result achieved on an oxide film using a slurry composition identical to that of the fourth sample.

As shown in FIG. 7, in the fifteenth and sixteenth samples, the range in the oxide thickness across the oxide film, i.e., the difference in thickness between the thickest portion of the oxide film and the thinnest portion of the oxide film, was approximately 750 Å and 650 Å respectively. On the other hand, the range in oxide thickness for the thirteenth and fourteenth samples were approximately 1,200 Å and 900 Å respectively. As a result, the range of oxide thickness across the polished oxide film was reduced as the mean particle surface area of the abrasive particles in the slurry composition was increased.

Experiment 5

FIG 8. is a graph illustrating the number of the defect points of the oxide film relative to the amount of the additive in the slurry composition. As reflected in FIG. 8, a nineteenth sample shows the measurement result concerning the number of the defect points, for example, micro scratches, formed while polishing an oxide film using a slurry including tetramethylammonium hydroxide at approximately 0.2 wt % and silicon oxide abrasive particles having a mean particle surface area of approximately 120 m²/g. A twentieth sample indicates the measurement result concerning the number of the defect points on the polished oxide film after polishing the oxide film using a slurry including tetramethylammonium hydroxide at approximately 0.4 wt % and silicon oxide abrasive particles having a mean particle surface area of approximately 120 m²/g. Additionally, a twenty-first sample represents the measurement result concerning the number of the defect points on the polished oxide film after polishing the oxide film using a slurry including tetramethylammonium hydroxide at approximately 0.2 wt % and silicon oxide abrasive particles having a mean particle surface area of approximately 130 m²/g.

Also in FIG. 8, a seventeenth sample shows the number of the defect points formed on the polished oxide film after polishing the oxide film using a slurry composition including tetramethylammonium hydroxide at approximately 0.2 wt % and silicon oxide abrasive particles having a mean particle surface area of approximately 90 m²/g. Also, an eighteenth sample shows the number of the defect points formed on the polished oxide film after polishing the oxide film using a slurry including the silicon oxide abrasive particles having the mean particle surface area of approximately 120 m²/g without the addition of any tetramethylammonium hydroxide to the slurry composition.

The defect points formed on the oxide film having diameters of more than approximately 0.3 μm were then measured with the apparatus of the SurfaceScan 6420 (manufactured by KLA-Tencor Corp., USA). As shown in FIG. 8, in the eighteenth sample, the number of the defect points formed on the oxide film was more than approximately 300, and the number of the defect points on the oxide film was approximately 50 in the nineteenth sample. Also, the number of the defect points formed on the oxide film were less than approximately 50 in the seventh and the twentieth samples, and the number of the defect points on the oxide film was less than approximately 100 in the twenty-first sample. As reflected by these defect measurements, the abrasive particles could easily agglomerate when the abrasive particles had a mean particle surface area of more than approximately 100 m²/g. Therefore, an additive including tetramethylammonium hydroxide may be added to slurry compositions having abrasive particles with a mean particle surface area of more than approximately 100 m²/g in order to prevent the number of the defect points due to the agglomeration of the abrasive particles from increasing. Additionally, as it is described above, the slurry could be more widely dispersed by colliding particles therein during the formation of the slurry and by the addition of tetramethylammonium hydroxide.

Experiment 6

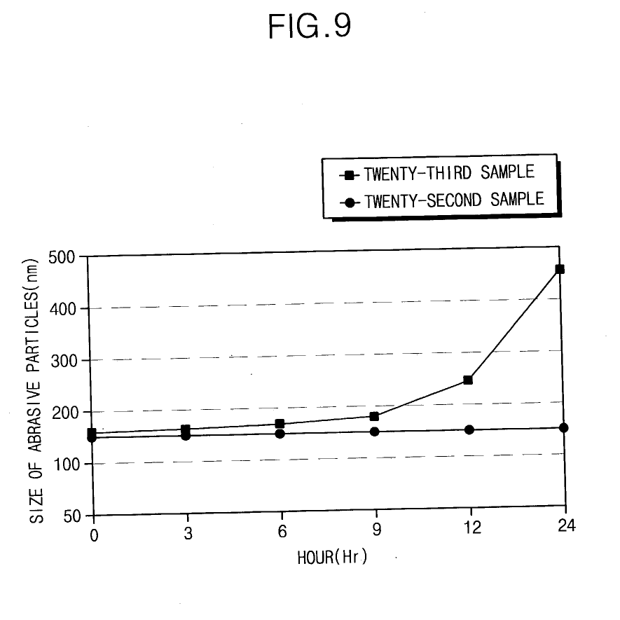

FIG. 9 is a graph showing the agglomeration tendency of slurry compositions relative to the amount of the additive in the slurry composition. As reflected in FIG. 9, a twenty-second sample shows the measurement result reflecting the relative stability of the size of the particles in the slurry composition as the slurry was forcibly circulated in the pipe having the diameter of approximately 0.3 inches (0.75 cm) with the flow rate of approximately 5 liters/min for about 24 hours. In this sample, the slurry composition included tetramethylammonium hydroxide at approximately 0.2 wt % and silicon oxide abrasive particles having a mean particle surface area of approximately 90 m²/g.

Also in FIG. 9, a twenty-third sample represents the measurement result reflecting variation in the size of particles in another slurry composition as the slurry was forcibly circulated in the pipe having the diameter of approximately 0.3 inches with the flow rate of approximately 5 liters/min for about 24 hours. In this sample, the slurry composition included silicon oxide abrasive particles having a mean particle surface area of approximately 90 m²/g but did not include any tetramethylammonium hydroxide.

As shown in FIG. 9, in the twenty-second sample, the measured size of the particles circulating in the slurry composition were relatively stable throughout the 24 hour duration of the test. However, as also reflected in FIG. 9, the measured size of the particles in the slurry composition of the twenty-third sample increased more than three-fold over the course of the same 24 hour test period. Thus, it can be noted that the inclusion of tetramethylammonium hydroxide as an additive in the slurry composition decreases the likelihood of agglomeration of the abrasive particles within the slurry. This ability to maintain the dispersion of the abrasive particles within the slurry composition will tend to reduce the number of the defect points formed on a film polished with such a slurry. That is, the defect points resulting at least in part from the agglomeration of the abrasive particles may be substantially reduced when the original degree of dispersion degree may be maintained within the slurry composition.

Table 1 shows the polishing rates and the polishing selectivities of several exemplary embodiments of slurry compositions and a comparative slurry composition.

TABLE 1

| | Nitride Polishing Rate | Polishing Selectivity |
|---|---|---|
| | (Å/minute) | (SiO₂/Si₃N₄) |
| Experiment 7 | 372.4 Å/min | 4.2 |
| Experiment 8 | 357.7 Å/min | 4.1 |
| Experiment 9 | 367.2 Å/min | 4.6 |
| Experiment 10 | 246.9 Å/min | 6.1 |
| Experiment 11 | 379.9 Å/min | 4.8 |
| Experiment 12 | 289.4 Å/min | 6.6 |
| Experiment 13 | 299.5 Å/min | 5.9 |
| Comparative | 567.5 Å/min | 4.0 |
| Experiment 7 | | |

Referring to Table 1, Experiment 7 shows the polishing rate of a nitride film polished using a slurry including tetramethylammonium hydroxide at approximately 0.3 wt %, methanol amine at approximately 0.1 wt % and silicon oxide abrasive particles having the mean particle surface area of approximately 130 m²/g. The selectivity reflected in Table 1 for each of the Experiments 7-13 and the Comparative Experiment 7 reflects the polishing selectivity of the nitride film relative to an oxide film determined for the particular slurry composition as described herein.

Experiment 8 represents the polishing rate of a nitride film polished using a slurry including tetramethylammonium hydroxide at approximately 0.3 wt %,dimethanol amine at approximately 0.1 wt % and silicon oxide abrasive particles having the mean particle surface area of approximately 130 m 2/g.

Experiment 9 represents the polishing rate of a nitride film polished using a slurry including tetramethylammonium hydroxide at approximately 0.3 wt %, trimethanol amine at approximately 0.1 wt % and silicon oxide abrasive particles having the mean particle surface area of approximately 130 m²/g.

Experiment 10 shows the polishing rate of a nitride film polished using a slurry including tetramethylammonium hydroxide at approximately 0.4 wt % and silicon oxide abrasive particles having the mean particle surface area of approximately 130 m²/g.

Experiment 11 shows the polishing rate of a nitride film polished using a slurry including tetramethylammonium hydroxide at approximately 0.3 wt %, ethylenediamine at approximately 0.1 wt % and silicon oxide abrasive particles having the mean particle surface are of approximately 130 m²/g.

Experiment 12 shows the polishing rate of a nitride film polished using a slurry including tetramethylammonium hydroxide at approximately 0.3 wt %, cetyltrimethylammonium bromide at approximately 0.1 wt % and silicon oxide abrasive particles having the mean particle surface area of approximately 130 m²/g.

Experiment 13 shows the polishing rate of a nitride film polished using a slurry including tetramethylammonium hydroxide at approximately 0.3 wt %, cetylpyriddinium chloride at approximately 0.1 wt % and silicon oxide abrasive particles having the mean particle surface area of approximately 130 m²/g.

Comparative Experiment 7 shows the polishing rate of a nitride film polished using a slurry including the silicon oxide abrasive particles having the mean particle surface area of approximately 130 m²/g without any other.

As shown in Table 1, the oxide/nitride polishing selectivities obtained in Experiments 7-13 were better than the selectivity achieved in Comparative Experiment 7. This result may be attributed to the presence of the additive(s) in the slurry compositions used in Experiments 7-13 which may have tended to reduce the polishing rate for nitride films. With the demonstrated oxide/nitride selectivities, the exemplary slurry compositions and polishing processes may be employed in polishing processes associated with the formation of trench isolation structures. Incorporating one or more of the noted additives into the slurry composition may be used to enhance the polishing selectivity to nitride by various degrees.

An exemplary oxide polishing process is described below. Starting with a substrate on which is provided an oxide film of approximately 6,000 Å, the oxide film is polished on a polishing apparatus (6EC manufactured by STRASBAUGH Inc. (USA)) using a slurry including silicon oxide abrasive particles having a mean particle surface area of approximately 130 m²/g, potassium hydroxide at approximately 0.2 wt % and tetramethylammonium hydroxide at approximately 0.2 wt %. The polishing process was conducted using the parameters and polishing conditions reflected below in Table 2.

TABLE 2

| Parameter | Setting |
|---|---|
| down force to the object to be polished | 4.0 psi |
| back pressure to the backside of the polishing pad | 1.5 psi |
| table speed of the polishing pad | 70 rpm |
| head speed.of the object to be polished | 70 rpm |
| polishing time | 1 mm |
| flow rate of the slurry composition | 150 ml/min |

With the polishing process having the process conditions as shown in Table 2, the observed polishing uniformity of the oxide film was approximately 2.5 percent with fewer than about 50 defect points being detected on the substrate surface, demonstrating the improved uniformity and decreased defect density that may be obtained using a slurry composition including abrasive particles with a mean particle surface area greater than 100 m²/g and additives such as potassium hydroxide and tetramethylammonium hydroxide.

An oxide film overlaying a nitride film may be polished in a similar fashion utilizing the polishing selectivity of a slurry composition according to the present invention of nitride film relative to oxide film. For example, a substrate may include a trench structure having a depth of approximately 3,500 Å covered with a first insulating film of approximately 1,000 Å of nitride formed on the substrate and on the sidewall and the bottom of the trench with a second insulating film of approximately 8,000 Å of oxide formed on the nitride film. The oxide and nitride films may be polished using the slurry including the silicon oxide abrasive particles having a mean particle surface area of approximately 130 m²/g, tetramethylammonium hydroxide at approximately 0.3 wt % and ethanol amine at approximately 0.1 wt % using the apparatus and process parameters noted above in Table 2 for polishing an oxide film. The resulting polishing process, with its oxide/nitride selectivity, reduces the dishing of the oxide film and the corrosion of the nitride film while providing improved polishing uniformity and reducing the number of the defect points formed during the polishing operation.

As it is described above, the improved slurry compositions may improve polishing uniformity without significantly reducing the polishing rate for a given film, thereby decreasing the failures resulting from defects generated during polishing processes and improving the reliability of the resulting semiconductor devices. The improved slurry compositions may also improve selectivity for a nitride film relative to an oxide film, thereby improving the process of forming trench isolation structures or other structures that present an oxide layer formed over a thinner nitride layer and enhancing a semiconductor manufacturing process.

Although certain exemplary embodiments of the present invention have been described, it should be understood that the present invention is not be limited to these embodiments and that various changes and modifications may be made by one skilled in the art without departing from the spirit and scope of the invention as hereinafter claimed.

What is claimed is:

1. An abrasive slurry comprising:
water; and
abrasive particles, the abrasive particles having a mean particle surface area of at least about 100 m²/g.

2. An abrasive slurry according to claim 1, wherein:
the abrasive particles have diameters of less than approximately 35 nm.

3. An abrasive slurry according to claim 1, wherein:
the abrasive particles include one or more oxides selected from a group consisting of silica,
ceria, zirconia, titania and alumina.

4. An abrasive slurry according to claim 1, wherein:
the abrasive particles are present in the slurry at between about 0.5 and 40 percent by weight.

5. An abrasive slurry according to claim 4, further comprising:
an additive, the additive being present in the slurry at between about 0.01 and 2.0 percent by weight.

6. An abrasive slurry according to claim 5, wherein:
the additive includes a dispersion stabilizer, a surfactant or a mixture thereof.

7. An abrasive slurry according to claim 5, wherein:
the additive includes at least one material selected from a group consisting of potassium hydroxide, sodium hydroxide, ammonium hydroxide and amine compounds.

8. An abrasive slurry according to claim 7, wherein:
the additive includes at least one amine compound selected from a group consisting of quadrivalent ammonium bases and salts thereof.

9. An abrasive slurry according to claim 7, wherein:
the additive includes a least one amine compound selected from a group consisting of tetramethylammonium hydroxide, tetraethylammonium hydroxide, tetramethylammonium chloride, tetraethylammonium chloride, tetramethylammonium fluoride and tetraethylammonium fluoride.

10. An abrasive slurry according to claim 7, wherein:
the additive includes at least one compound selected from a group consisting of ethanol amine, dimethanol amine, trimethanol amine, ethylene diamine, cetyltrimethylammonium bromide and cetylpyridinium chloride.

11. An abrasive slurry according to claim 7, wherein:
the additive includes a first compound selected from a group consisting of ethanol amine, dimethanol amine, trimethanol amine, ethylene diamine, cetyltrimethylammonium bromide and cetylpyridinium chloride; and
a second compound selected from a group consisting of potassium hydroxide, sodium hydroxide, ammonium hydroxide, tetramethylammonium hydroxide, tetraethylammonium hydroxide, tetramethylammonium chloride, tetraethylammonium chloride, tetramethylammonium fluoride and tetraethylammonium fluoride.

12. An abrasive slurry according to claim 11, wherein:
the first compound and the second compound are present in the slurry in a weight percent ratio of between 1:1 and 1:5.

13. An abrasive slurry according to claim 12, wherein:
the first compound and the second compound are present in the slurry in a weight percent ratio of about 1:3.

14. A method of preparing an abrasive slurry according to claim 1 comprising:
preparing abrasive particles having a mean particle surface area of at least about 100 m²/g, the mean particle surface area being obtained from primary particles of the abrasive particles; and
mixing the abrasive particles with water to form an abrasive slurry.

15. A method of preparing an abrasive slurry comprising:
preparing abrasive particles having a mean particle surface area of at least about than 100 m²/g, the mean particle surface area being obtained from primary particles of the abrasive particles;
mixing the abrasive particles with water to form an abrasive mixture;
pressing the abrasive mixture; and
dispersing the abrasive particles in an aqueous solution to form an abrasive slurry.

16. A method of preparing an abrasive slurry according to claim 15, wherein:
the primary particles are characterized by an average diameter of less than about 35 nm.

17. A method of preparing an abrasive slurry according to claim 15, wherein:
the abrasive particles include at least one material selected from a group consisting of silica, ceria, zirconia, titania and alumina.

18. A method of preparing an abrasive slurry according to claim 17, further comprising:
incorporating an additive, the additive including at least one material selected from the group consisting of potassium hydroxide, sodium hydroxide, ammonium hydroxide and amine compounds.

19. A method of preparing an abrasive slurry according to claim 18, wherein:
the additive includes a first compound selected from a group consisting of ethanol amine, dimethanol amine, trimethanol amine, ethylene diamine, cetyltrimethylammonium bromide and cetylpyridinium chloride; and
a second compound selected from a group consisting of potassium hydroxide, sodium hydroxide, ammonium hydroxide, tetramethylammonium hydroxide, tetraethylammonium hydroxide, tetramethylammonium chloride, tetraethylammonium chloride, tetramethylammonium fluoride and tetraethylammonium fluoride.

20. A method of polishing a film formed on a surface of a substrate comprising:
preparing an abrasive slurry including abrasive particles with a mean particle surface area of at least about 100 m²/g, water and an additive, the additive including at least one compound selected from the group consisting of potassium hydroxide, sodium hydroxide, ammonium hydroxide and amine compounds;
dispensing the abrasive slurry onto a polishing pad;
contacting the polishing pad with the surface of the substrate; and
inducing relative motion between the surface of the substrate and the polishing pad while maintaining contact between the polishing pad and the surface of the substrate to remove a portion of the film.

21. A method of polishing a film formed on a surface of a substrate according to claim 20, wherein:
the film is an oxide film, the relative motion of the polishing pad and the surface of the substrate removing the oxide film at a rate of at least 2,500 Å/minute with a remaining portion of the oxide film exhibiting a thickness uniformity of less than about 3 percent.

22. A method of polishing a film formed on a surface of a substrate according to claim 20, wherein:
the film includes both an oxide film and a nitride film, the relative motion of the polishing pad and the surface of the substrate removing the oxide film at a first rate and removing the nitride film at a second rate, the ratio of the first rate to the second rate being at least 4.

23. A method of polishing a film formed on a surface of a substrate according to claim 22, wherein:
the ratio of the first rate to the second rate being at least 6.

24. A method of polishing a film formed on a surface of a substrate according to claim 20, wherein:
the abrasive particles include one or more oxides selected from a group consisting of silica, ceria, zirconia, titania and alumina.

25. A method of polishing a film formed on a surface of a substrate comprising:
forming an abrasive slurry according to claim 5;
dispensing the abrasive slurry onto a polishing pad;
contacting the polishing pad with the surface of the substrate; and
inducing relative motion between the surface of the substrate and the polishing pad while maintaining contact between the polishing pad and the surface of the substrate to remove a portion of the film.
